(19) United States
(12) Patent Application Publication
(10) Pub. No.: US 2021/0143808 A1
(43) Pub. Date: May 13, 2021

(54) TIMING EVENT DETECTION

(71) Applicant: Minima Processor Oy, Oulu (FI)

(72) Inventors: Ari PAASIO, Littoinen (FI); Matthew TURNQUIST, Salo (FI); Lauri KOSKINEN, Helsinki (FI)

(73) Assignee: Minima Processor Oy, Oulu (FI)

(21) Appl. No.: 16/625,478

(22) PCT Filed: Jun. 22, 2017
(86) PCT No.: PCT/FI2017/050475

§ 371 Date: Dec. 20, 2019

(51) Int. Cl. H03K 5/1534; H03K 19/003; H03K 5/05

(52) U.S. Cl. CPC H03K 5/1534; H03K 5/05; H03K 19/00323

(57) ABSTRACT

It is an objective to provide timing event detection. According to a first aspect, a device, comprises: a clocked conditional buffer configured to set an output of the clocked conditional buffer to a first state during a non-detection period; the clocked conditional buffer further configured to toggle the output from the first state to the second state during a detection period, wherein the toggling being enabled by either one of the two states; and the clocked conditional buffer further configured to guarantee that the output is toggling only to one direction during the detection period. This may prevent false event detections. Furthermore, with respect to a timing point of view, one is able to operate without pulses, where pulse width may be difficult to manage in low voltages.

### TECHNICAL FIELD

The present application relates to event detection in digital technology, and more particularly to timing event detection.

### BACKGROUND

In electronics, a flip-flop or latch is a circuit that has two stable states, typically a low state and a high state, and can be used to store state information. A flip-flop may be a bistable multivibrator. The circuit can be made to change state by signals applied to one or more control inputs and will have one or two outputs. It is the basic storage element in sequential logic. Flip-flops and latches are fundamental building blocks of digital electronics systems used in computers, communications, and many other types of systems.

Flip-flops and latches are used as data storage elements. A flip-flop stores a single bit (binary digit) of data; one of its two states represents a “one” and the other represents a “zero”. Such data storage can be used for storage of state, and such a circuit is described as sequential logic. When used in a finite-state machine, the output and next state depend not only on its current input, but also on its current state (and hence, previous inputs). It can also be used for detection of pulses, and for synchronizing variably-timed input signals to a reference timing signal.

Flip-flops can be either simple (transparent or opaque) or clocked (synchronous or edge-triggered). Although historically the term flip-flop has generically referred to both simple and clocked circuits, in modern usage it is common to reserve the term flip-flop exclusively for discussing clocked circuits; the simple ones are commonly called latches. The latch may be level-sensitive, whereas a flip-flop may be edge-sensitive. When a latch is enabled it becomes transparent, while a flip flop's output only changes on a single type (positive going or negative going) of clock edge. When the latch is disabled, it becomes non-transparent.

In conventional digital design flow, combinational logic delay constraints are static in the sense that the resulting circuit from synthesis should meet the worst case operation condition delays in order to guarantee the circuit operation. If the run-time delay is longer than analyzed during the design time, correct circuit operation cannot be secured. In a conventional design, meeting timing requirements introduces overdesign leading to both area and power-dynamic and static-consumption increase in the system.

When energy consumption is intended to be reduced, consequently the voltage of the circuit must be low in order to achieve this. This proposes new and additional challenges for the operation and configuration of the latch. The lower the voltage becomes, the higher the susceptibility of the circuit to variations becomes, and in smaller CMOS process nodes the variation worsens. Both lead to increasing overdesign. Therefore, methods to find out the actual dynamic operating condition become increasingly important. That dynamic operating condition can be used in Dynamic Voltage and Frequency scaling, for example. To minimize margin and overdesign, the dynamic operation condition should be that of the actual logic and not an external canary circuit or logic circuit copy. In FIG. 1, there may be seen that events are registered, the Event signal rises always when D changes. One embodiment is when data arrives late (the second transition 2 in the data D) and is a timing error. Then the event signal flags the timing error. The error signal can then be used, for example, to trigger an instruction replay in processors.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

It is an objective to provide timing event detection. The object is achieved by the features of the independent claims. Further implementation forms are provided in the dependent claims, the description and the figures.

According to a first aspect, a device comprises: a clocked conditional buffer configured to set an output of the clocked conditional buffer to a first state during a non-detection period; the clocked conditional buffer further configured to toggle the output from the first state to the second state during a detection period, wherein the toggling being enabled by either one of the two states; and the clocked conditional buffer further configured to guarantee that the output is toggling only to one direction during the detection period. This may prevent false event detections. Furthermore, with respect to a timing point of view, one is able to operate without pulses, where pulse width may be difficult to manage in low voltages.

In an embodiment, the clocked conditional buffer is further configured to lack an ability to toggle back to other direction than said one direction.

In an embodiment, the clocked conditional buffer is configured with the conditional toggling taking place with the first state, and the clocked conditional buffer is configured with the conditional toggling taking place with the second state.

In an embodiment, further including a second clocked conditional buffer.

In an embodiment, the two buffers are connected in parallel.

In an embodiment, the two buffers are connected in series.

In an embodiment, the first buffer comprises: a first clocked conditional inverting buffer circuit; and the second buffer comprises a second clocked conditional inverting buffer circuit; wherein the first and the second clocked conditional inverting buffers circuits are configured to output the first state when a latch of the buffers is non-transparent; wherein the first clocked conditional inverting buffer is configured to toggle the output from the first state to the second state; and wherein the second clocked conditional inverting buffer is configured to toggle the output from the second state to the first state.

In an embodiment, the first clocked conditional inverting buffer is configured to pull-up or pull-down depending on how the states are configured.

In an embodiment, the second clocked conditional inverting buffer is configured to pull-up or pull-down depending how the states are configured.

In an embodiment, a detection phase of the latch comprises that the latch is configured transparent.

In an embodiment, a non-detection phase of the latch comprises that the latch is configured non-transparent.

In an embodiment, the first and the second clocked conditional inverting buffers receive an inversed clock of a clock of the latch, and the first clocked conditional inverting buffer receives a data signal as input and outputs a first comparative signal, wherein the second clocked conditional inverting buffer receives the first comparative signal as input and outputs a second comparative signal.

In an embodiment, the first comparative signal is delayed and an inverted version of the data signal and the second comparative signal is delayed and an inverted version of the first comparative signal.

In an embodiment, the clocked conditional buffer is configured outside a signal path of the latch.

In an embodiment, wherein a generate block of an event detection device comprises at least the clocked conditional buffer, wherein the device comprises the event detection device.

In an embodiment, further including a pull-down keeper configured to prevent leakage due to floating logic levels of the first comparative signal XD.

In an embodiment, a transistor is configured to be common to both clocked conditional inverting buffers so that pull-up paths of the inverting buffers are controlled by the common transistor.

In an embodiment, further comprising a detect block, wherein the detect block receives the outputs of the clocked conditional buffer and the data signal and is further configured to detect an event indicative of an event for the latch.

According to a second aspect, a detection block of an event detection device of a latch comprises: a first pull-down path; and a second pull-down path, wherein the paths are coupled in parallel and both are coupled to a common pull-up path. Timing mismatches between two event detection cases may be thereby balanced.

Many of the attendant features will be more readily appreciated as they become better understood by reference to the following detailed description considered in connection with the accompanying drawings.

### DESCRIPTION OF THE DRAWINGS

The present description will be better understood from the following detailed description read in light of the accompanying drawings, wherein:

FIG. 1 illustrates a timing diagram showing the concept of timing event detection;

FIG. 2a illustrates a schematic representation of a circuit diagram of a clocked conditional buffer with inverting functionality, according to an embodiment;

FIG. 2b illustrates a schematic representation of a circuit diagram of a clocked conditional buffer with inverting functionality, according to another embodiment;

FIG. 3a illustrates a schematic representation of a circuit diagram of a clocked conditional buffer with non-inverting functionality, according to an embodiment;

FIG. 3b illustrates a schematic representation of a circuit diagram of a clocked conditional buffer with non-inverting functionality, according to another embodiment;

FIG. 4a illustrates a schematic representation of a block diagram having two inverting same set-type structures in series, according to an embodiment;

FIG. 4b illustrates a schematic representation of a block diagram having two inverting opposite set-type structures in parallel, according to an embodiment;

FIG. 4c illustrates a schematic representation of a block diagram having one inverting and one non-inverting same set-type structures in parallel, according to an embodiment;

FIG. 5 illustrates a schematic block diagram of a sequential circuit having a latch with event detection;

FIG. 6 illustrates a schematic representation of a block diagram of a device configured for event detection according to an embodiment;

FIG. 7 illustrates a schematic representation of a block diagram of a device configured for generating delayed and inverted versions of an input data signal according to an embodiment;

FIG. 8 illustrates a schematic representation of a circuit diagram of a clocked condition inverting buffer with low output at a non-transparent phase and conditional pull-up at a transparent phase according to an embodiment;

FIG. 9 illustrates a schematic representation of a circuit diagram of a generate block of a device according to an embodiment;

FIG. 10 illustrates a schematic representation of a circuit diagram of a generate block of a device according to another embodiment;

FIG. 11 illustrates a schematic representation of a circuit diagram of a detection block of a device according to an embodiment;

FIG. 12 illustrates a schematic representation of a circuit diagram of a detection block of a device having a pull-down arrangement according to another embodiment; and

FIG. 13 illustrates a schematic representation of a circuit diagram of a detection block of a device having a pull-up arrangement according to an embodiment.

Like references (such as numerals and abbreviations in capitals) are used to designate like parts in the accompanying drawings.

### DETAILED DESCRIPTION

The detailed description provided below in connection with the appended drawings is intended as a description of the embodiments and is not intended to represent the only forms in which the embodiment may be constructed or utilized. However, the same or equivalent functions and structures may be accomplished by different embodiments.

Typically, the latch 20 has two different states, a first state and a second state. The states of the latch may be described as being low LOW or high HIGH, which illustrate an example of two different states of a state machine, for example as illustrated in FIG. 1. It should be noted that other kinds of states may be used instead or in addition to low and high.

There is a general trend to increase the efficiency of microprocessors. The main efficiency increase comes from ultra-low or low voltage subthreshold operation of the circuit and latch 20 and other digital technology processor components. With the low to ultra-low voltage operation, it is feasible to operate approximately at the minimum energy point, which is where energy per digital operation is reduced. Additionally, the elimination of timing margins may bring gains at nominal operating voltages.

A purpose of an embodiment may be to detect data changing, such as an event, during a detection time, for example a clock phase that a data latch 20 is transparent or a separately generated detection time. The detection device comprises a clocked conditional buffer that is configured to generate output for event detection in either case, the input having changed from low to high or high to low during the detection period. According to an embodiment, one requires two clocked conditional buffers to be able to detect data changes for both directions. However, due to various connection possibilities of two clocked conditional buffers, an embodiment is more concisely described by introducing the operation of one clocked conditional buffer first.

A clocked conditional buffer may be referred to as a circuit arrangement with one input and one output, wherein during the non-detection phase, for example the associated monitored latch is non-transparent, the output of the buffer is set to either low or high and the input of the buffer has no effect on the output. During the detection phase, the buffer can conditionally toggle its output to the other polarity that it was set to. The toggling operation may be dependent on the input polarity only and the toggling may thus not dependent on input change. The operation of the clocked conditional buffer is configured such that it is not allowed for the buffer to toggle back to the set value once it has been toggled once from the set value, and this functionality gives the buffer the feature ‘conditional’.

Due to the operation of the clocked conditional buffer, an event during the detection period has occurred, when the buffer output has been toggled and the input of the buffer is at a logic level that does not toggle the buffer. This type of event condition can be easily evaluated by a following digital block.

There are various embodiments to implement a circuit block with the functionality described above. The buffer can be set to either low LOW or high HIGH state during the non-detection phase and can be toggled to one direction by either low LOW or high HIGH input level during the detection phase. In a CMOS case, NMOS-transistors are used to pull a node to low LOW and PMOS transistors are used to pull a node high HIGH. However, especially at low voltages, NMOS-transistor can also be used to pull-up and PMOS-transistor can be used for pulling down a node. When using NMOS for pull-down and PMOS for pull-up, two different exemplary buffers can be constructed, where in the first buffer, the set phase sets the output LOW, and in the second exemplary buffer the output is set high HIGH during the non-detection phase. Transistor level arrangements are shown in FIG. 2 with their associated symbols.

FIG. 2a illustrates a clocked conditional buffer with inverting functionality. In the buffer the set value may be low LOW and toggling input level low LOW.

In FIG. 2a, the output OUT is set low LOW during the non-detection phase by an NMOS-transistor M3 and its associated control voltage being HIGH. At the same time, the pull-up functionality is inhibited by a PMOS transistor M1, and thus the input IN of the buffer has no effect on the output OUT during this period. During the detection period, the inputs of transistors M1 and M2 are low LOW, which configures the buffer such that if the input voltage of the buffer (the gate voltage of the input IN related transistor M2) is LOW, the output OUT of the buffer toggles from low LOW to high HIGH. Additionally, the buffer is not configured for the once toggled output to be pulled down any more during the detection phase. Since the low LOW input signal level makes the output OUT to toggle and produces an output level high HIGH, this arrangement can be considered to be an inverting clocked conditional buffer, or clocked conditional inverting buffer as alternatively referred to. The associated symbol indicates the toggling direction by an arrow inside the buffer triangle. Additionally, the circle at the output of the triangle—forming a well-known inverter symbol—indicates an inverting operation and therefore this structure may be toggled by input level low LOW.

FIG. 2b illustrates a clocked conditional buffer with inverting functionality, wherein the set value may be high HIGH and toggling input level high HIGH.

In FIG. 2b, the output OUT is set high HIGH during the non-detection phase and the toggling ability is from high HIGH to low LOW while the structure is inverting. The associated symbol is also shown with similar reasoning for the triggering arrow direction as with FIG. 1a).

Since it is also possible to have (at least partial) a pull-up functionality with an NMOS transistor and (at least partial) a pull-down functionality with PMOS transistor, non-inverting buffers may also be embodied implementations. Two embodied configurations are shown in FIG. 3 with modified input transistor types of those from FIG. 2. FIG. 3a illustrates the clocked conditional buffer with non-inverting functionality, having the set value low LOW and toggling input level high HIGH. In FIG. 3a the output OUT is set low LOW during the non-detection phase and pulled up during the detection phase if the input IN is high HIGH. Therefore, the conditional toggling operation may be non-inverting. This is shown in the associated symbol by having omitted the inversion representing circle at the output of the buffer. FIG. 3b illustrates the clocked conditional buffer with non-inverting functionality, having set value HIGH and toggling input level low LOW. The structure of FIG. 3b is set HIGH during the non-detection phase and toggled by the input level low LOW during the detection phase.

To be able to detect data input change to both directions one requires two clocked conditional buffers where one monitors the input changing from high HIGH to low LOW and the other monitors the low LOW to HIGH transition. There are various possibilities to connect the two buffers to receive the input value during the detection phase so that changes in the data during that phase can be monitored. The buffers can be connected in parallel or in series where the only requirement for the selection of the types of the two buffers is that one is monitoring the LOW-to-HIGH transition and the other is monitoring the HIGH-to-LOW transition. In FIG. 4 there are three embodiments of connections shown for two buffers. FIG. 4a illustrates two inverting same set-type structures in series. First block monitors LOW-to-HIGH transition and the second block monitors HIGH-to-LOW transition. FIG. 4b illustrates two inverting opposite set-type structures in parallel. The bottom block monitors LOW-to-HIGH transition and the top block monitors HIGH-to-LOW transition. FIG. 4c illustrates one inverting and one non-inverting same set-type structures in parallel. The bottom block monitors LOW-to-HIGH transition and the top block monitors HIGH-to-LOW transition.

The arrangement for the following logic to extract the event occurrence from the inputs and outputs of the buffers varies from buffer type selection to selection. One of the most efficient manners to connect the two buffers is to connect two similar inverting buffers in series. This type of arrangement is described in more detail next.

According to an embodiment, a data signal polarity change may be detected during the latch transparency period. Consequently, a possible event may be detected. FIG. 5 shows an embodiment of a circuit 10 for event detection, where the data D and clock CLK inputs of a latch 20 are connected to a transition detector 10 (which may be referred to as the circuit) which generates the event signal when the data transitions within the clock high period (for a positive edge triggered latch). The circuit 10 configured for the detection, may be coupled to the latch 20 as illustrated in FIG. 2, so that the circuit 10 is outside the main signal path of the latch 20. The circuit 10 comprises a generate block (for example reference 100 in FIG. 3) of the event detection device. The generate block 100 is configured to create comparative signals of the data signal D for the event detection purposes. The circuit 10 receives, and may require, only the clock CLK and data signal D as its input. The circuit 10 may comprise clocked conditional buffer (for example in FIGS. 2-4) or two or more clocked inverting buffers (for example in FIG. 6) that establish a generate block 100 of the event detection device. The inverting buffer, in general, were described earlier with respect to FIGS. 2-4 and it may be similar inverting buffer to the inverting buffers. The inverting buffers always output a low state when the latch 20 is non-transparent, for example in the non-detection phase. Furthermore, the first clocked inverting buffer may only perform a toggle operation in one direction (for example change state from low LOW to high HIGH) without the opposite toggle operation (for example change state from high HIGH to low LOW). The second clocked inverting buffer may only perform the opposite toggling operation with respect to the first inverting buffer (for example pull-down operation without the pull-up operation.

Consequently, because the latch 20 is transparent during the clock CLK being high HIGH, the output of the circuit 10 is always low LOW during the non-transparent phase of the latch 20. This may eliminate the possibility of the event signal. Furthermore, because each of the inventing buffers may only operate in one direction, from a timing point of view the circuit and latch 20 may be operated completely without pulses, where a pulse width may be extremely difficult to manage, especially in the low voltages.

According to an embodiment, the event detection device comprises a detect block (for example reference 101 in FIG. 5). The detect block 101 is configured to detect the possible event based on the data signal D and comparative signals generated by the generate block. A pull-down path of the detect block 101 may be implemented as separate pull-down paths for different detection cases. This may balance the timing mismatches between the different event detections.

Referring to FIG. 6, it illustrates a schematic representation of a block diagram of an event detection device configured for event detection according to an embodiment. The circuit operation may be described by the device illustrated in FIG. 6. The device comprises a generate block 100 and a detect block 101.

The generate block 100 receives a clock signal CLK and a data input signal D as inputs. The generate block 100 is configured for generating a delayed version XD and/or an inverted version XXD of the data input D for the detect block 101. The generate block 100 also passes on the data input D to the detect block 101. The detect block 101 is configured for performing a simple logic operation between the input D and it's delayed and/or inverted versions XD, XXD. According to an embodiment, to have a simple detect block 100, the inverted/delayed versions XD, XXD of the data input D may be essentially set to predetermined logic values during the non-detection phase within the generate block 100. The detect block 101 may trigger an event as an outcome of the signals D, XD and/or XXD. For example, a certain event may be triggered by a certain combination of the states of the signals D, XD, and XXD. The event may be further used and processed within a computing device for detecting the event.

The generate and detect blocs 100,101 are described separately, whereby both blocks 100,101 can have different embodiments. The circuit diagrams in FIGS. 2-13 illustrate their components, such as transistors M1 . . . M7, inputs IN, D, XD, XXD, RESET, CLK, XCLK, outputs OUT, XD, XXD, EVENT, and voltages VDD and ground GND. The respective interconnections of the components are illustrated in FIGS. 2-13.

Referring to FIG. 7, a block diagram of an inverting buffer chain is shown. The first inverting buffer essentially produces a delayed and inverted version XD of the data input D. The second inverting buffer receives the signal XD as it's input. The second inverting buffer essentially produces a delayed and inverted version XXD of the input XD.

According to an embodiment, the generation of XD and XXD may be blocked during the non-transparent phase of the main latch operation. Therefore, the simple inverters of FIG. 7 may be replaced by a circuit diagram as shown in FIG. 8, which illustrates a modified inverting buffer.

The inverting buffer, for example, comprises transistors M1, M2 and M3. The inverting buffer receives inputs of an inversed clock XCLK and a data signal IN. Furthermore, the inverting buffer is connected to the operation voltage VDD and ground GND. In the embodiment of FIG. 8, the output of the inverting buffer is always low LOW when the inverted version of the clock CLK (denoted as XCLK) is high HIGH. Here it may be assumed that the main latch is transparent during the clock CLK being high HIGH, and thus the output OUT of the circuit arrangement of FIG. 8 is always low LOW during the non-transparent phase of the main latch 20. This may be beneficial for arranging the detect block 101. Moreover, as a distinction to a normal inverter, the pull-down transistor of the inverting buffer may be removed so that when the inverse clock XCLK is low LOW, the circuit allows a conditional pull-up operation, but at the same time lacks the pull-down functionality. This type of operation may be beneficial from the timing point of view, since one is able to operate completely without pulses, where the pulse widths are difficult to manage, especially in low voltages.

The generate block 100, according to an embodiment, is illustrated in FIG. 9. Two clocked conditional inverting buffer form a chain and produce outputs signals XD and XXD. The clocked conditional inverting buffer may be as described according to the embodiment of FIG. 6. The second inverting buffer comprises transistors M4, M5, M6 and receives an inverted clock XCLK and the output of the first inverting buffer XD as its input. The second inverting buffer outputs a comparative signal XXD. The first clocked conditional inverting buffer is configured for detecting the data input D transition from low LOW to high HIGH during the detection phase (XCLK being the state LOW). The second clocked conditional inverting buffer is configured for detecting the input D state transition from high HIGH to low LOW during the detection phase.

The operation of the embodiment of FIG. 9 is next described in more detail with four different possibilities for the data signal input D during the detection phase. These are merely examples of the possible options, and there may be other kinds of state transitions and detections.

In the first option, the input D is high HIGH at the beginning of the detection phase and stays high HIGH for the whole detection period. At the beginning of the detection period, the signal XD is low LOW and the signal XD stays low LOW for the whole detection period. Furthermore, at the beginning of the detection period, since the signal XD is low LOW, the signal XXD is pulled high HIGH, and the signal XXD stays high HIGH for the whole detection period.

In the second option, the input D is low LOW at the beginning of the detection phase and stays low LOW for the whole detection period. At the beginning of the detection period, the signal XD is low LOW and is pulled high HIGH, and the signal XD stays high HIGH for the whole detection period. At the beginning of the detection period, the signal XXD is initially low LOW, and since the signal XD is pulled high HIGH, the signal XXD stays low LOW for the whole detection period.

In the third option, the input D is low LOW at the beginning of the detection phase and turns high HIGH during the detection period. At the beginning of the detection period, the signal XD is low LOW and the signal XD is pulled high HIGH, and the signal XD stays high HIGH for the whole detection period, since the first clocked conditional inverting buffer lacks the pull-down operation. At the beginning of the detection period, the signal XXD is initially low LOW, and since the signal XD is pulled high HIGH, the signal XXD stays low LOW for the whole detection period.

In the fourth option, the input D is high HIGH at the beginning of the detection phase and turns low LOW during the detection period. At the beginning of the detection period, the signal XD is low LOW and the signal XD stays low LOW until the signal D goes low LOW, and then the signal XD is pulled high HIGH and stays high HIGH for the rest of the detection period. At the beginning of the detection period, since the signal XD is low LOW, the signal XXD is pulled high HIGH, and the signal XXD stays high HIGH for the whole detection period, since the second clocked conditional inverting buffer lacks the pull-down operation.

From these four possible scenarios, according to the embodiment, an event EVENT is detected in the third and fourth options and not detected in the first and second options. The event may be extracted by monitoring options where signals D and XD are simultaneously high HIGH or where signals XD and XXD are simultaneously high HIGH. The monitoring is performed by the detect block 101 for example as described in the embodiments below.

According to an embodiment, there are certain design issues that are considered for the generate block 101. For example, the nodes XD and XXD may be conditionally floating, leaving them possibly susceptible of either transistor leakage or power supply disturbance to destroy the floating logic levels. Moreover, the timing of the clocked conditional inverting buffers may be arranged in such a manner that if the first clocked conditional inverting buffer is to be pulled high HIGH during the beginning of the detection period (signal D being low LOW), the second clocked conditional inverting buffer does not have time to go high HIGH (for example for the third option above).

FIG. 10 illustrates an embodiment of the generate block 101. An embodiment addresses the floating node challenge of the first clocked conditional inverter. Another embodiment proposes an arrangement where the number of transistors within the generate block 101 can be reduced.

The conditional floating of the node XD can be removed by adding a weak pull-down keeper M7 as illustrated in FIG. 10. During an event EVENT as described in the fourth option above, there is a pull-up path activated through transistors M1 and M2 simultaneously to the keeper M7 having an active pull-down, and therefore a short circuit current flows through transistors M1, M2 and M7. This is considered so that the transistors M 1, M2 and M7 may be operated so that no considerable short circuit occurs, or a safety component is included within the circuit. Another embodiment comprises combining the clocked pull-up paths to be controlled by one common transistor, instead of both clocked conditional inverting buffers having a separate clocked pull-up path. In FIG. 10, the transistor M1 is shared between both conditional inverting buffers. In some cases, especially when trying to avoid the signal XXD going high HIGH in the beginning of the detection period as described in the third option above, it may be better to have separate pull-up transistors for the conditional inverting buffers, where the second conditional inverting buffer may be designed to have a slower rise time. In case of having a shared pull-up path, relative rise times can still be appropriately controlled by transistors M2 and M5 as illustrated in FIG. 10.

FIG. 11 illustrates a schematic representation of a circuit diagram of a detection block 101 of a device according to an embodiment. Furthermore, FIG. 12 illustrates a schematic representation of a circuit diagram of a detection block 101 of a device having a pull-down arrangement according to another embodiment.

The detect block 101 may be implemented by performing a logic function of the signals XD(D+XXD), or according to another embodiment having the inverted version as illustrated FIG. 11. The embodiment of FIG. 11 offers robust detection even at lower operating voltages and has a maximum of two stacked transistors. Timing-wise, according to the embodiment in the generate block 101, an event EVENT may be detected when either one of the inputs of the clocked conditional inverting buffers changes during the detection period, while the corresponding output is already high HIGH. The structure presented in FIG. 8, even though being compact, has a pull-down transistor, whose input change is triggering the detection of an event EVENT, closest to the ground GND in case when the signal XD goes high HIGH and the signal XXD is already high HIGH, for example as described with respect to the fourth option above.

This is not the case in the third option above when the signal D goes high HIGH during the detection period, since the corresponding pull-down transistor M5 in FIG. 11 is not closest to the ground GND. There may be some timing mismatches between the two event detections for the third and the fourth options. In order to balance these timings, the pull-down path according to the arrangement shown in FIG. 12 may be implemented in an embodiment. In FIG. 12, there are totally separate pull-down paths for both detection options. The pull-up branch may be the same in this case as compared to FIG. 11, where the PMOS-part of transistors M4, M5 is connected to the PU-node, since the arrangement of FIG. 12 does not change the underlying logic function. Although FIG. 12 describes two paths, there may be several paths such as four different pull-down paths. The logic operation of the OR tree may be shortened by having the pull-down paths as illustrated in FIG. 12.

Whereas the detection arrangement of FIG. 11 is able to evaluate events related to one generate block 100, it is also possible to evaluate signals from multiple generate blocks simultaneously using a pull-up network arrangement and having multiple pull-down networks associated with that pull-up arrangement. An exemplary pull-up network is shown in the embodiment of FIG. 13, where one can connect multiple pull-down networks directly taken from the embodiments FIG. 11 or FIG. 12 to the PD node. The reset signal RESET is set when an event EVENT has been detected, and can be unset since the structure has a keeper structure built in.

According to an embodiment, more than one pull-down networks may be connected to the same pull-up network. Moreover, there is no need to have a dedicated reset transistor RESET in the pull-down path (in series with other pull-down transistors) taking care of inhibiting short-circuit currents during the reset operation RESET. This additional transistor may create a transistor stack of three in the pull-down path. The transistor may be an NMOS transistor.

The transistor may encompass both N-type and P-type metal oxide field effect (MOS) transistors, depending on circuit. Further encompassed are MOS transistors where different parameters such as VT, material type, gate size and configuration, insulator thickness, etc. vary. According to another embodiment, the transistor can also include other FET-type and bipolar-junction transistors and other types of transistors.

The functionality described herein can be performed, at least in part, by one or more hardware logic components. Alternatively, or in addition, the functionality described herein can be performed, at least in part, by one or more computer program product components such as software components. According to an embodiment, the device comprises a processor configured by the program code when executed to execute the embodiments of the operations and functionality described.

Any range or device value given herein may be extended or altered without losing the effect sought. Also any embodiment may be combined with another embodiment unless explicitly disallowed.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item may refer to one or more of those items.

The steps of the methods described herein may be carried out in any suitable order, or simultaneously where appropriate. Additionally, individual blocks may be deleted from any of the methods without departing from the spirit and scope of the subject matter described herein. Aspects of any of the embodiments described above may be combined with aspects of any of the other embodiments described to form further embodiments without losing the effect sought.

The term ‘comprising’ is used herein to mean including the method, blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

1.-20. (canceled)

21. A device, comprising:
a clocked conditional buffer having a data input, a further input, and an output,
the clocked conditional buffer configured to set the output to a first state during a non-detection period defined by a first value at the further input;
the clocked conditional buffer further configured to toggle the output from the first state to the second state during a detection period defined by a second value at the further input, wherein the toggling is enabled by only one of the two possible states at the data input; and
the clocked conditional buffer further configured to guarantee that the output is toggling only to one direction during the detection period.

22. The device of claim 21, wherein the clocked conditional buffer is further configured to lack an ability to toggle, during the detection period, to an additional direction other than the one direction.

23. The device of claim 21, wherein:
the device comprises a generate block and an event detection device coupled to receive signals generated by the generate block, and
the generate block comprises at least one of the clocked conditional buffer according to claim 21.

24. The device of claim 21, further including a second clocked conditional buffer in which the toggling is enabled during the detection period by that one of the two possible states at the data input of the second clocked conditional buffer that is different from the state at the data input of the first clocked conditional buffer that enables the toggling of the first clocked conditional buffer during the detection period.

25. The device of claim 24, wherein the two clocked conditional buffers are connected in parallel.

26. The device of claim 24, wherein the two clocked conditional buffers are connected in series.

27. The device of claim 24, wherein:
the first clocked conditional buffer comprises a first clocked conditional inverting buffer,
the second clocked conditional buffer comprises a second clocked conditional inverting buffer,
the first clocked conditional inverting buffers and the second clocked conditional inverting buffer are each configured to output a first state when a latch associated with the clocked conditional buffers is non-transparent,
the first clocked conditional inverting buffer is configured to perform the toggling of its output from the first state to the second state, and
the second clocked conditional inverting buffer is configured to perform the toggling of its output from the second state to the first state.

28. The device of claim 27, wherein the first and second clocked conditional buffers are outside a signal path of the latch.

29. The device of claim 27, wherein a transistor is configured to be common to the first and second clocked conditional inverting buffers so that pull-up paths of the first and second clocked inverting buffers are controlled by the common transistor.

30. The device of claim 27, wherein the detection period is a period during which the latch is transparent, and the non-detection period is a period during which the latch is non-transparent.

31. The device of claim 27, wherein:
the first and the second clocked conditional inverting buffers receive an inversed clock (XCLK) of a clock (CLK) of the latch,
the first clocked conditional inverting buffer receives a data signal as input and the first clocked conditional inverting buffer outputs a first comparative signal, and
the second clocked conditional inverting buffer receives the first comparative signal as input and the second clocked conditional inverting buffer outputs a second comparative signal.

32. The device of claim 31, wherein the first comparative signal is a delayed and inverted version of the data signal and the second comparative signal is a delayed and inverted version of the first comparative signal.
